(19) United States
(12) Patent Application Publication
(10) Pub. No.: US 2025/0075360 A1
(43) Pub. Date: Mar. 6, 2025

(54) COMPONENT WITH INTEGRATED NICKEL DIFFUSION LAYER

(71) Applicant: KAMAX Holding GmbH & Co. KG, Homberg (Ohm) (DE)

(72) Inventors: Ali Solimani, Marburg (DE); Dennis Dutenhöfner, Homberg (Ohm) (DE)

(73) Assignee: KAMAX Holding GmbH & Co. KG, Homberg (Ohm) (DE)

(21) Appl. No.: 18/290,735

(22) PCT Filed: Jul. 19, 2022
(86) PCT No.: PCT/EP2022/070211

§ 371 Date: Jan. 19, 2024

(30) Foreign Application Priority Data
Jul. 20, 2021 (DE) DE102021118765.6

(51) Int. Cl. C25D 5/50; B32B 15/01; F16B 33/00

(52) U.S. Cl. CPC C25D 5/50; B32B 15/013; F16B 33/008; B32B 2311/22

(57) ABSTRACT

Component with a component (1) made of steel, wherein the component is at least partially coated with a nickel diffusion layer (10), and the layer thickness of the nickel diffusion layer (10) is 1-500 μm and the nickel diffusion layer (10) has a nickel content, based on the total weight of the nickel diffusion layer, of 2 wt. % above the nickel content of the steel up to a maximum concentration, the nickel content in the nickel diffusion layer (10) increasing continuously in the direction of the surface (12) of the nickel diffusion layer (10) from 2% by weight up to the maximum concentration and the maximum concentration being 20-100% by weight.

### CROSS-REFERENCE TO RELATED APPLICATIONS

This application is a U.S. National Stage Application under 35 U.S.C. § 371 of International Application No. PCT/EP2022/070211, filed Jul. 19, 2022, which claims the benefit of and priority to German Patent Application No. DE 10 2021 118 765.6, filed Jul. 20, 2021, the contents of which are hereby incorporated herein by reference in their entireties.

### TECHNICAL FIELD

The invention relates to a component with a component made of steel, in which the component is coated with a nickel diffusion layer. In particular, the invention may also relate to a fastening means, such as a screw or a nut, which has a component made of steel, which in turn is coated with a nickel diffusion layer.

### BACKGROUND

Metal components, especially high-strength and ultra-high-strength components, are susceptible to hydrogen embrittlement. Hydrogen embrittlement is caused by the penetration of hydrogen into the metal structure of the components and leads to intercrystalline cracking when the components are stressed. This phenomenon is known as hydrogen-induced stress cracking corrosion.

### SUMMARY

Component with a component made of steel, wherein the component is at least partially coated with a nickel diffusion layer, and the layer thickness of the nickel diffusion layer is 1-500 μm and the nickel diffusion layer has a nickel content, based on the total weight of the nickel diffusion layer, of 2 wt. % above the nickel content of the steel up to a maximum concentration, the nickel content in the nickel diffusion layer increasing continuously in the direction of the surface of the nickel diffusion layer from 2% by weight up to the maximum concentration and the maximum concentration being 20-100% by weight.

### BRIEF DESCRIPTION OF THE DRAWINGS

FIG. 1 is a schematic view of a component according to the invention:

FIG. 2 is a schematic view of a tensile strain diagram for a device according to the invention; and

FIG. 3 is a schematic view of a tensile-elongation diagram for a device not according to the invention.

### DETAILED DESCRIPTION

The present invention is based on the task of reducing the tendency to hydrogen-induced stress corrosion cracking in steel components.

This problem is solved with a component with a steel component according to claim 1, with a fastening means according to claim 2, with a method for manufacturing a component according to claim 10 and with a use according to claim 14. Further features, embodiments and advantages are shown in the subclaims, the description and the figures.

One aspect of the invention relates to a component with a component made of steel, wherein the component is at least partially coated with a nickel diffusion layer, the layer thickness of the nickel diffusion layer is 1-500 μm, preferably 3-500 μm, and the nickel diffusion layer has a nickel content, based on the total weight of the nickel diffusion layer, of 2 wt.-% above the nickel content of the steel up to a maximum concentration, wherein the nickel content in the nickel diffusion layer in the direction of the surface of the nickel diffusion layer is continuously increased from 2 wt.-% up to the maximum concentration. % above the nickel content of the steel up to a maximum concentration, wherein the nickel content in the nickel diffusion layer increases continuously in the direction of the surface of the nickel diffusion layer from 2% by weight up to the maximum concentration and the maximum concentration is 20-100% by weight.

A further aspect of the invention can relate to a component with a component made of steel, wherein the component is a fastener, wherein the component made of steel has and/or forms a threaded region, wherein the component is at least partially coated, in particular in the threaded region, with a nickel diffusion layer, wherein the layer thickness of the nickel diffusion layer is 1-500 μm, in particular 3-500 μm, wherein the nickel diffusion layer has a nickel content, based on the total weight of the nickel diffusion layer, of 2 wt.-% above the nickel content of the steel up to a maximum concentration, wherein the nickel content in the nickel diffusion layer in the direction of the surface of the nickel diffusion layer is continuously increased from 2 wt.-% up to the maximum concentration. % above the nickel content of the steel up to a maximum concentration, wherein the nickel content in the nickel diffusion layer increases continuously in the direction of the surface of the nickel diffusion layer from 2% by weight up to the maximum concentration, and wherein the maximum concentration is 20-100% by weight. The fastening means is expediently a screw; in particular a high-strength or even an ultra-high-strength screw, or a nut, in particular a high-strength or even an ultra-high-strength nut.

Another aspect of the invention relates to a method of manufacturing a component with a component made of steel, comprising the steps of:
a) Providing a component with a steel component,
b) applying a nickel layer comprising ≥30% by weight of nickel, based on the total weight of the nickel layer, to the steel component, and then
c) heating the component and the nickel layer to 750 to 950° C. for at least 10 minutes, preferably for at least 20 minutes, thereby producing a nickel diffusion layer on the steel component.

A further aspect of the invention relates to the use of the component according to the invention for reducing hydrogen embrittlement.

Surprisingly, the nickel diffusion layer on steel components according to the invention acts as a pronounced barrier against the penetration of hydrogen by diffusion, thereby increasing the resistance of the components to hydrogen-induced stress corrosion. The diffusion process and thus the formation of the nickel diffusion layer also improves the adhesion of the nickel layer to the steel, as the nickel layer grows together with the steel of the component, so to speak. The prevention of hydrogen-induced stress corrosion is particularly advantageous and desirable for fasteners, which usually have a high and often dynamic axial stress, because these fasteners, which can be screws or nuts, for example, are essential for many assemblies. For example, the failure of a fastener, in particular a high-strength or ultra-high-strength bolt, can therefore have drastic consequences for man or machine, such as in the case of an engine head bolt, a bridge bolt, a cylinder head bolt, a chassis bolt and/or a battery mounting bolt. In other words, the invention can also relate to a vehicle, an engine, in particular a cylinder head, a chassis arrangement or a battery arrangement with a component, in particular a fastening means, with the nickel diffusion layer according to the invention or a structure, in particular such as a bridge.

To produce the nickel diffusion layer, the steel component, for example a high-strength or ultra-high-strength screw, is coated with a nickel layer. All processes known in the prior art are suitable for coating, in particular electroplating or coating by PVD (physical vapor deposition). Alternatively or preferably, the coating can also be applied by laser melting and/or laser metal deposition. These processes allow particularly cost-effective coating. Furthermore, the coating can also be applied by means of build-up welding, which can also be referred to as cladding, in order to achieve a coating that is particularly resistant to mechanical stress.

In the subsequent heating step, nickel diffuses into the iron lattice of the steel and iron diffuses into the nickel layer. This creates a nickel diffusion layer that is thicker than the original nickel layer. In addition to the iron, any alloy components of the steel also diffuse into the nickel layer. The nickel diffusion layer has a concentration gradient in which the nickel concentration increases continuously in the direction of the surface of the nickel diffusion layer. The iron concentration decreases continuously in the direction of the surface of the nickel diffusion layer. Furthermore, the concentration of any alloy components of the steel decreases continuously in the direction of the surface of the nickel diffusion layer. The surface is, in particular, the surface which delimits the nickel diffusion layer distally opposite or facing away from the steel component. The nickel diffusion layer is therefore bounded by the surface, in particular distally opposite the steel component. This surface can itself be coated and/or the surface can, for example, be a free surface which is not coated. In other words, the surface can be exposed or covered by a coating and/or by another component. The surface is therefore in particular the area or the resulting interface at which the maximum concentration is present.

A component made of steel within the meaning of the invention can be understood in particular to mean that at least a part of the component, i.e. a volume region, is made of steel. It is particularly preferred if the weight of the component consists of at least 80%, preferably at least 90%, and particularly strongly preferred at least 95%, of steel or is formed by the steel component. In this way, a particularly good mechanical strength of the component, in particular of the fastening means, can be achieved. In order to increase the mechanical strength, it is particularly preferable if the steel component is in one piece. In particular, “one-piece” can be understood to mean that at least the one-piece part has been created in a primary forming process and/or is cohesive.

For the purposes of the invention, the nickel diffusion layer is defined as the range of the steel component having a nickel content, based on the total weight of the nickel diffusion layer, of 2% by weight above the nickel content of the steel up to a maximum concentration, the maximum concentration being 20-100% by weight of nickel. For example, if the steel used contains no nickel, the nickel diffusion layer is the layer that has a nickel content of 2% by weight up to the maximum concentration of nickel. Pure nickel may be present on the surface of the nickel diffusion layer, i.e. the maximum concentration is then 100% by weight. In this case, for a steel without nickel content, the nickel concentration in the nickel diffusion layer is between 2% and 100% by weight.

If, in the above case, the iron diffuses to the surface of the original nickel layer during diffusion, the maximum concentration is below the original nickel content of the nickel layer, for example below: 100% by weight if a pure nickel layer has been applied. For example, it can then be 98% by weight. In this case, the nickel diffusion layer has a nickel content of 2-98% by weight.

If the steel of the component of the component is an alloy steel with a nickel content of, for example, 1% by weight, the nickel content in the nickel diffusion layer is 3% by weight up to the maximum concentration. If the maximum concentration on the surface is 100% by weight, the nickel content in the nickel diffusion layer is therefore 3-100% by weight. In the case of diffusion of the iron and/or other alloy components of the substrate or the steel component to the surface during the heating step and a resulting maximum concentration of 95% by weight at the surface of the nickel diffusion layer, the nickel content in the nickel diffusion layer in this case is 3-95% by weight.

For the purposes of the invention, “coated” with a nickel diffusion layer is understood to mean that the steel component has a nickel diffusion layer on the outside in cross-section. This means in particular that the steel component is bordered in at least one spatial direction by a firmly adhering layer of shapeless material, which is a nickel diffusion layer. Advantageously, the coating can comply with DIN 8580-especially in the version valid on May 1, 2021.

The thickness of the nickel diffusion layer depends, among other things, on the thickness of the nickel layer originally applied and the duration and temperature of the heating step. According to the invention, the thickness of the nickel diffusion layer is 1-500 μm, preferably 3-300 μm, particularly preferably 5-150 μm, especially 7-100 μm and most preferably 10-70 μm. The lower thicknesses of the preferred embodiments of the nickel diffusion layer are particularly advantageous for precisely fitting components.

The “layer thickness” of the nickel layer and the nickel diffusion layer is understood to be the average layer thickness if the top or bottom surface has unevenness. For this purpose, at least three measurements of the layer thickness are taken, preferably 6 to 8 measurements, and the arithmetic mean of the measured values is determined.

The maximum concentration of nickel in the nickel diffusion layer is 20-100% by weight. Preferred are 40-100 wt. %, further preferred 70-100 wt. %, particularly preferred 70-99.5 wt. %, especially 80-99.2 wt. % and most preferred 90-99.0 wt. %. These maximum concentrations of nickel in the nickel diffusion layer lead to a particularly advantageous embodiment with regard to hydrogen embrittlement.

The nickel content in the nickel diffusion layer increases continuously in the direction of the surface of the nickel diffusion layer. The increase takes place from 2% by weight above the nickel content of the steel up to the maximum concentration, for example 70-99.5% by weight. Preferably, the nickel content in the nickel diffusion layer increases vertically in the direction of the surface of the nickel diffusion layer. It is further preferred that the nickel content in the nickel diffusion layer increases continuously perpendicularly in the direction of the surface of the nickel diffusion layer.

In order to further adapt the surface of the component with a steel component to the respective application, it is preferred that a further layer is applied to the nickel diffusion layer, in particular selected from nickel layer, corrosion protection layer, wear protection layer and sliding layer. Phosphate layers, zinc-nickel layers and zinc flakes are preferred, particularly if the component is a fastener, advantageously a screw or a bolt. These layers are particularly advantageous in terms of improving corrosion resistance and/or friction properties.

Advantageously, the steel component is coated with the nickel diffusion layer in areas with increased notch effect and/or adjacent areas to areas with increased notch effect, in particular in areas of a thread, under a head, e.g. of a screw, notches or grooves. Areas with an increased notch effect are in particular areas which have a notch effect factor of more than 1.1, preferably more than 1.4, particularly preferably more than 1.9 and particularly strongly preferred more than 2.1. In an area of a thread, a groove or under a (screw) head or in the transition to the screw head, an area with an increased notch effect within the meaning of the invention is therefore advantageously to be seen. An adjacent area to an area with increased notch effect is to be understood as an area which is at a maximum distance of 10 mm, preferably at a maximum distance of 5 mm and particularly preferably at a maximum distance of 2 mm, from the area with increased notch effect. Alternatively, an adjacent area to an area with increased notch effect can also be present if it is at a maximum distance of 10%, preferably at a maximum of 5%, particularly preferably at a maximum of 2%, of the largest main dimension of the steel component from the area with increased notch effect.

A nickel layer within the meaning of the present invention is preferably a layer whose nickel content, based on the total weight of the nickel layer, is ≥30 wt. %, more preferably ≥50 wt. %, even more preferably ≥70 wt. %, in particular ≥90 wt. % and most preferably 100 wt. %.

The nickel layer can comprise a nickel alloy, preferably a Ni—Co, Ni—Mn and/or Ni—Co—Mn alloy. In these nickel layers, which are also referred to as nickel alloy layers, the nickel content, based on the total weight of the layer, is ≥30% by weight, more preferably ≥50% by weight, even more preferably ≥70% by weight.

The steel of the component of the component can be a high-alloy steel or a low-alloy steel, whereby a low-alloy steel is preferred. Alternatively or additionally preferred, the steel, in particular low-alloy steel, can also be an unalloyed steel. For the purposes of the invention, a low-alloy steel is understood to be a steel whose total proportion of alloying elements does not exceed 5% by weight, in particular of the alloying elements Cr, Mo, V, Ni, Mn, Al, B and Ti, based on the total weight of the steel. The term low-alloy steel within the meaning of the invention also includes micro-alloyed steels. For the purposes of the invention, a high-alloy steel is a steel whose total proportion of alloying constituents is greater than 5% by weight, in particular of the alloying elements Cr, Mo, V, Ni, Mn, Al, B and Ti, based on the total weight of the steel. For the purposes of the invention, an unalloyed steel is understood to be a steel which contains up to 0.8% by weight of carbon and less than 1% by weight of manganese, based on the total weight of the steel.

In a preferred embodiment of the invention, the steel of the component of the component is a low-alloy steel with a nickel content<1% by weight, based on the total weight of the steel component. Furthermore, the steel is preferably a high-strength or ultra-high-strength steel. The advantage of low-alloy steel is that it can be tempered particularly well and at the same time or alternatively can provide a particularly high degree of strength, so that the advantages achieved by the invention, in particular with regard to hydrogen embrittlement, can be realized particularly well.

In a preferred embodiment of the invention, the microstructure of the steel component in the component is at least predominantly martensitic, bainitic and/or dual-phase (retained austenite, ferrite and/or martensite). Preferably, the microstructure of the steel component in the component is at least 80% by weight, in particular at least 90% by weight martensitic, bainitic and/or dual-phase (retained austenite, ferrite and/or martensite), in each case based on the total weight of the steel component. These microstructures give the component according to the invention a particularly high strength and toughness. These microstructures can be subjected to high and often dynamic axial stress, so that the reduction of hydrogen embrittlement is particularly advantageous for them. The microstructure in the nickel diffusion layer can differ from the microstructure of the remaining steel component (the so-called base material). The element distribution in the nickel diffusion layer is advantageously characterized by a high concentration of two elements, namely iron and nickel. Depending on the composition of the steel component, the other alloying elements may be present as dissolved elements or as intermetallic precipitates in the nickel diffusion layer.

The component according to the invention is preferably a high-strength or ultra-high-strength component, in particular with strengths above 1000 MPa, preferably above 1200 MPa, particularly preferably above 1400 MPa and particularly strongly preferably above 1600 MPa. Preferred high-strength and ultra-high-strength components are high-strength or ultra-high-strength screws or fasteners, springs, leaf springs, disk springs and chain drives, formed components and/or structural components. Further or alternatively preferred is the component according to the invention, in particular the high-strength or ultra-high-strength component, preferably a welded component, an additive-manufactured component or a case-hardened component. Welded components in particular can be subject to high hydrogen embrittlement due to welding, so that the invention can be used particularly well here. In the case of a case-hardened component, the component is additionally case-hardened during manufacture, in particular by carburizing, nitriding or nitrocarburizing. The component is then coated with nickel, as described above.

A formed component is in particular a component that has been formed by means of a forming step, in particular a cold forming process. In the case of a formed component, in particular a cold-formed component, it is particularly advantageous to avoid brittleness, in particular hydrogen scarfing, because formed components already have a certain degree of brittleness due to the accumulated forest dislocations. A structural component within the meaning of the invention exists in particular if the component is a load-bearing component. In particular, this structural component has two load-introducing sections, which advantageously have load-introducing structures, such as mounting recesses or openings, and a transmission area arranged between the load-introducing sections, which can and/or does transmit a load, in particular a bending load and/or tensile load, from one load-introducing section to the other load-introducing section. Advantageously, at least one, preferably all load introduction sections, and/or the transmission area is provided with the nickel diffusion layer according to the invention. Forming the component in such a way that the steel has a strength of over 1000 MPa, preferably over 1200 MPa, particularly preferably over 1400 MPa and particularly strongly preferably over 1600 MPa, is particularly advantageous, since hydrogen embrittlement is always more decisive in these strength classes, so that the invention can play out its advantages precisely at these strengths.

The fastening means according to the invention can in particular be non-positive fastening means, such as screws, bolts or nuts. Force-locking fastening means are characterized in particular by the fact that they have a threaded section for bracing or fastening, in particular with an external thread or an internal thread. For example, the threaded section can therefore be an external thread or an internal thread. Advantageously, this threaded section is incorporated in a component of the fastening means, which is made of steel. In other words, the steel component can have a threaded section which can be coated with the nickel diffusion layer described above and below. Advantageously, at least three, preferably at least five, and particularly preferably all threads of the threaded portion are coated with the nickel diffusion layer. Advantageously, at least the distal end threads are the threads that are coated with the nickel diffusion layer. The end threads are in particular the threads that form one end of the threaded section or form the end regions of the threaded section or the thread run-out. Alternatively or additionally preferably, the nickel diffusion layer can also be present in a shank area. The shank area is in particular an area of the fastener which lies between the head, in particular the screw head, and the threaded section of the fastener and mechanically connects them to one another. Preferably, the shank area can be threadless and/or designed as a cylindrical section. The diameter of the shank can be larger, smaller or equal to the thread diameter in the threaded section. By applying or forming a nickel diffusion layer—as described above and below—in the shank area, the mechanical properties of the fastener can be positively influenced there in accordance with the invention. The screws are advantageously high-strength or ultra-high-strength screws.

The steel component in the component according to the invention is at least partially coated with a nickel diffusion layer, i.e. the component is partially or completely coated with a nickel diffusion layer.

In a particularly preferred embodiment of the invention, the component is a high-strength or ultra-high-strength screw. A high-strength screw is understood to be a screw with a tensile strength of at least 800 MPa. High-strength screws are, for example, screws of strength classes 8.8, 10.9 and 12.9. In particular, the strength classes of the invention correspond to ISO 898-1 in its version valid in January 2021. An ultra-high-strength screw is understood to be a screw with a tensile strength of at least 1200 MPa and/or advantageously 1400 MPa. Ultra-high-strength screws are, for example, screws of strength classes 12.8, 12.9, 14.8, 14.9, 15.8, 15.9, 16.8, 16.9, 17.8 and 12.8U, 12.9U, 14.8U, 14.9U, 15.8U, 15.9U, 16.8U, 17.8U. A high-strength screw is a screw that is at least high-strength, but it can also be ultra-high-strength. Preferably, it is a high-strength or ultra-high-strength screw with a strength of over 1000 MPa. The component of the component or the screw which has the nickel diffusion layer is particularly preferably the shank and/or the threaded area of the screw; because it is precisely here that strong dynamic loads occur during operation of the screw, which increase the susceptibility of the screw to hydrogen embrittlement, which can be prevented or at least significantly reduced by the invention. The screw can have a head with tool-engaging surfaces, whereby these tool-engaging surfaces form an internal or external hexagon in particular. It is particularly preferred if the entire screw is coated with the nickel diffusion layer.

In a preferred embodiment of the invention, the component with a component made of steel is a fastener, wherein the component has and/or forms a threaded region and/or a shank region, wherein the component is at least partially coated with a nickel diffusion layer, in particular in the threaded region and/or in the shank region, wherein the layer thickness of the nickel diffusion layer is 1-500 μm, wherein the nickel diffusion layer has a nickel content, based on the total weight of the nickel diffusion layer, of 2 wt. % by weight above the nickel content of the steel up to a maximum concentration, wherein the nickel content in the nickel diffusion layer increases continuously in the direction of the surface of the nickel diffusion layer from 2% by weight above the nickel content of the steel up to the maximum concentration, and wherein the maximum concentration is 20-100% by weight, preferably 40-100% by weight, preferably wherein the steel is a low-alloy steel or an unalloyed steel.

As described above, the fastener is preferably a high-strength or ultra-high-strength fastener, in particular a screw or nut.

The invention also relates to a method of manufacturing the component according to the invention. The method according to the invention comprises the steps of:
a) Providing a component with a steel component,
b) applying a nickel layer comprising ≥30% by weight of nickel, based on the total weight of the nickel layer, to the steel component, and
c) Heating the component and the nickel layer to 750 to 950° C. for at least 20 minutes, producing a nickel diffusion layer on the steel component.

Steps a), b) and c) above are carried out in this order. As described above, the thickness of the nickel diffusion layer depends, among other things, on the thickness of the nickel layer originally applied and the duration and temperature of the heating step. The nickel layer applied in step b) preferably has a thickness of 0.1-100 micrometers (μm), more preferably 0.5-80 μm, even more preferably 1-50 μm, particularly preferably 1.5-30 μm, especially 2.5-15 μm.

Preferably, heating takes place in the heating step for at least 10 minutes, more preferably for at least 15 minutes and most preferably for at least 20 minutes. It is further preferred that heating takes place for 10-600 minutes, more preferably for 15-400 minutes and most preferably for 20-180 minutes. The heating takes place at 750-950° C. for the specified periods of time, preferably at 800-950° C., particularly preferably at 820-920° C., especially at 830-900° C. This achieves an advantageous interdiffusion between iron and nickel to form the nickel diffusion layer, which counteracts hydrogen embrittlement.

Heating step c) may be followed by further steps, in particular heat treatment step d). Alternatively or additionally preferably, however, the tempering step can also take place during and/or at the same time or together with the heating step c). In other words, tempering and heating can be carried out together in one step. This allows the nickel diffusion layer to be produced particularly quickly and cost-effectively, especially in the case of a low-alloy steel. For example, martensitic quenching and tempering (preferably by quenching in oil, air and/or water) or bainitization (preferably in a salt bath) can be carried out. Martensitic quenching and tempering or bainitization are carried out under the usual conditions.

Heating step c) can therefore be a separate heating step, for example in a furnace, or the heating step can take place during the tempering step of the component, for example during austenitization of the steel. Preferably, the heating step takes place during the hardening and tempering of the component.

In a preferred embodiment of the invention, the method of manufacturing a component comprises the steps of:
a) Providing a component with a component made of steel, wherein the component is a fastener and the component has and/or forms a threaded portion and/or shank portion, where the steel is a low-alloy steel or an unalloyed steel,
b) application of a nickel layer comprising 40-100% by weight of nickel, based on the total weight of the nickel layer, on the steel component, in particular in the thread area and/or shank area, and
c) heating the component and the nickel layer to 750 to 950° C. for at least 10 minutes, preferably at least 20 minutes, thereby producing a nickel diffusion layer on the steel component.

In the method of the invention, the preferred and particularly preferred features of the component are also preferred and particularly preferred.

The invention also relates to the use of the component according to the invention for avoiding or reducing hydrogen embrittlement. The use preferably comprises the use of the described, preferred components for avoiding or reducing hydrogen embrittlement, for example a fastener having a threaded portion. This relates in particular to the reduction or avoidance of hydrogen embrittlement in the component due to hydrogen that can penetrate from the outside, for example when the component is used as intended. This can be the case, for example, when the component according to the invention, such as a fastener, is used in a corrosive environment. The nickel diffusion layer according to the invention then protects the component particularly effectively against hydrogen embrittlement by reducing or preventing the penetration of hydrogen into the component.

A preferred embodiment of the invention relates to the use of the component according to the invention, in particular fastening means, in a battery arrangement or a fuel cell. Batteries or fuel cells often produce a relatively large amount of hydrogen, and here the nickel diffusion layer according to the invention can prevent hydrogen embrittlement with particular advantage.

The invention also relates to a battery arrangement and/or fuel cell, comprising a component according to the invention, in particular a fastening means according to the invention. Here, the advantages of avoiding hydrogen embrittlement described above are achieved particularly effectively due to the relatively high quantities of hydrogen produced in battery arrangements or fuel cells.

The advantageous embodiments of the process according to the invention described above are also advantageous for this preferred process, in particular the aforementioned preferred and particularly preferred layer thicknesses, temperatures, heating times and/or advantageous components, etc.

The microstructure of the steel component before heating step c) can be ferritic, ferritic-pearlitic, bainitic, GKZ-annealed or a mixed microstructure. After heat treatment step d), the microstructure of the component can, in a preferred embodiment, be martensitic, bainitic or ferritic-martensitic or dual-phase (retained austenite, ferrite and/or martensite).

The invention also relates to a component with a component made of steel, obtainable by the method according to the invention. Advantageously, the component and/or the component made of steel may also have the aforementioned features with regard to the method.

It is understood that the above-mentioned features and the features to be explained below can be used not only in the combinations indicated, but also in other combinations or on their own, without going beyond the scope of the present invention. The aforementioned advantages of features or of combinations of several features are merely exemplary and can take effect alternatively or cumulatively. The combination of features of different embodiments of the invention or of features of different patent claims is possible in deviation from the selected references of the patent claims.

The following example explains the invention further.

### Measuring Method for Determining Coating Thickness:

The thickness of the nickel layer is preferably measured with a micrometer, for example using the method according to ASTM C664-10 (as published in 2020, test method A). For this purpose, the thickness of the component is essentially measured before and after coating and the coating thickness is calculated from the difference.

The thickness of the nickel diffusion layer can be determined by first measuring the thickness of the component after it has been coated with the nickel layer and the nickel diffusion layer has been formed by the heating step. The nickel diffusion layer is then removed, for example by grinding, and the composition of the material is analyzed, for example by chemical analysis of the removed material or chemical analysis of the remaining surface material. Wet chemical methods or atomic force microscopy (AFM), for example, can be used as an analysis method. Material is removed as long as the removed material has a nickel content of at least 2% by weight above the nickel content of the steel, based on the total weight of the nickel diffusion layer. After removal of the nickel diffusion layer, the nickel content of the steel on the surface of the component is just below 2% by weight above the nickel content of the steel and the thickness of the component is measured again with a micrometer. The thickness of the nickel diffusion layer is calculated from the difference.

Alternatively, the thickness of the nickel diffusion layer can be determined using the method according to ASTM C664-10 (as published in 2020, test method B). For this purpose, the layer thickness is essentially determined in cross-section using an optical microscope. It is also possible to determine the thickness of the nickel diffusion layer in the cross-section using energy dispersive X-ray spectroscopy (EDS, EDX, EDXS or XEDS).

### Example

Production of a nickel diffusion layer and influence on hydrogen-induced stress corrosion cracking

A component with a nickel diffusion layer is manufactured by producing the component from the substrate material steel using axial cold forging. The starting material is fed to the forming machine in the form of a wire coil. The formed product has the geometry of a screw. This is followed by cleaning in a sodium hydroxide solution and inhibited HCl to remove the lubricant (phosphate) required for forming in order to prevent diffusion of the phosphorus into the substrate during subsequent heat treatment. The surface is activated using 10% sulphuric acid. A nickel layer is then applied by electrodeposition using a standard nickel bath (55° C. for 15 min, current density 0.8-1 A/dm²). A Ni layer of 2-3 μm is produced (determination according to the method described above). This is followed by rinsing in deionized water (VE-Wasser) and drying.

An additional nickel layer<1 μm thick can be applied before the nickel layer for better adhesion, e.g. using the so-called Ni-Strike process.

After the coating has been applied, the component is austenitized at a temperature of 850° C. for 30 minutes in a protective gas atmosphere. During this time, the nickel interdiffuses into the substrate material and vice versa. A zone is formed which has a gradient of nickel concentration. To achieve the desired microstructure and mechanical properties of the component, quenching is carried out immediately after austenitizing. A suitable microstructure is set during the quenching process. Within the diffusion layer, the material produced transforms according to its local Ni concentration. The resulting component had a tensile strength of 1600 MPa-1650 MPa.

Experimental evaluation of the influence of the nickel diffusion layer on hydrogen-induced stress corrosion cracking:

The phenomenon of hydrogen-induced stress corrosion cracking in high-strength steel materials generally requires three external influencing factors. These are:
1. Material with a susceptibility to hydrogen-induced stress corrosion cracking
2. High mechanical tensile or bending stresses in the component
3. Hydrogen supply in the surrounding area

To evaluate the material behavior with regard to hydrogen-induced stress corrosion cracking, a test setup is therefore suitable in which the other two factors are reproducibly mapped. The test setup according to DIN EN ISO 7539-7 is therefore used for the assessment.

The evaluation in accordance with DIN EN ISO 7539-7 chapter 7.3 according to “Integral of the nominal stress/strain curve” has proven to be particularly precise. In any case, the system consisting of the above-mentioned influencing factors in the state without hydrogen supply in the environment is always compared with the system with hydrogen supply in the environment for characterization. After evaluating the characteristic value of the “integral of the nominal stress/strain curve”, a value for the total deformation energy absorbed by the component is obtained for each of the two states. Using the formula

$$HE = 1 - \frac{{W}_{B h} ( Verformungsenergie mit H - Beladung )}{{W}_{Bu} ( Verformungsenergie ohne H - Beladung )}$$

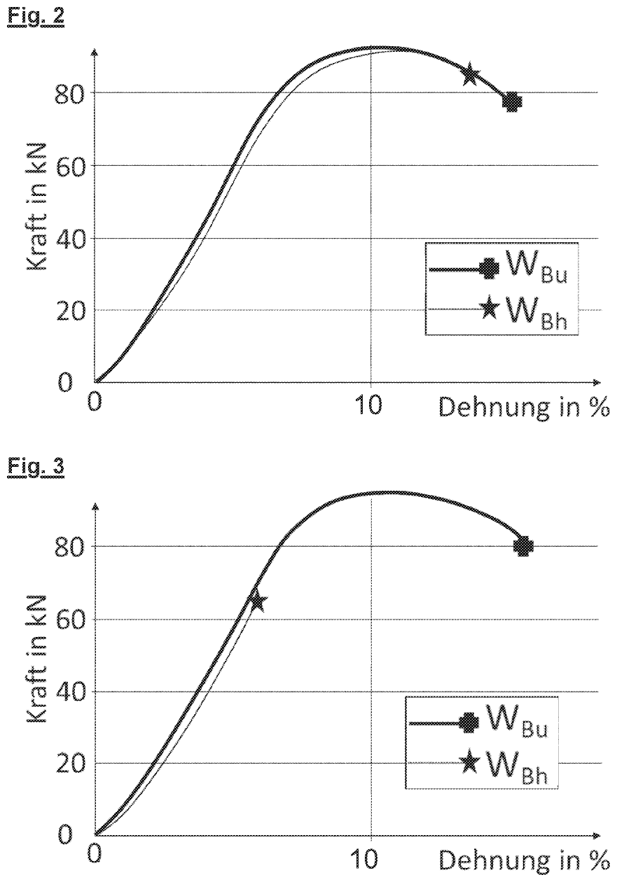

the so-called HE value is determined from the two calculated deformation energies. The HE value can be between 0 and 1. A value of HE=0 means no influence on the material properties, while HE=1 means failure under hydrogen without load (the latter is a theoretical extreme value and not possible in reality). The integrals of the nominal stress/strain curve for WBh and WBu are shown schematically in FIG. 2 for the above-mentioned screw components.

Material required to carry out the test:
1. Components in the condition to be tested
2. 37% HCl
3. Demineralized water
4. Instrumented tensile/compression testing machine

The test to characterize the screws with integrated nickel diffusion layer is carried out by determining the reference value without hydrogen load WBu. This is determined using the mean value of three samples with an elongation rate of 0.0067 l/s in the instrumented tensile/compression testing machine. WBu=268 J could be determined.

To determine the deformation energy under the influence of hydrogen WBh, three samples from the same production batch were exposed to 37% HCl for 10 minutes as above in order to introduce hydrogen through the cathodic partial reaction of acid corrosion. Immediately afterwards, the samples treated in this way were analyzed at an elongation rate of 0.02 mm/min. (total test duration 4 h) in the instrumented tensile/compression testing machine to determine WBh. WBh=246 J was determined.

Consequently, an overall susceptibility to hydrogen-induced stress corrosion cracking of HE=0.08 was determined.

FIGS. 2 and 3 show the comparison between the known components and the component according to the invention with integrated nickel diffusion layer.

Further advantages and features of the present invention are shown in the following description with reference to the figures. Individual features of the embodiments shown can also be used in other embodiments, unless this has been expressly excluded.

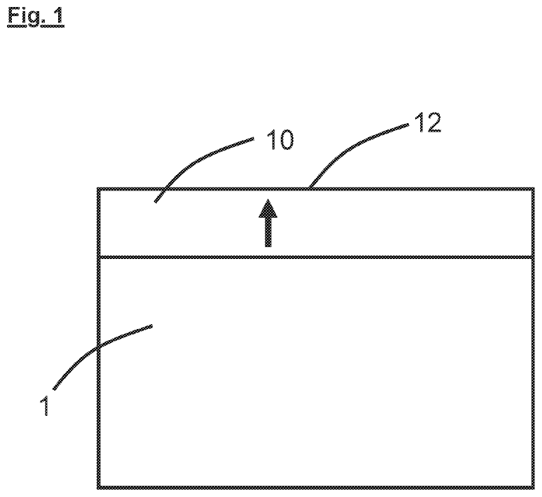

FIG. 1 shows a component according to the invention. The component has a component 1 made of steel. In particular, the component can be a fastener or a spring. The component 1 is at least partially coated with a nickel diffusion layer 10, the thickness of the nickel diffusion layer being 1 to 500 μm. The arrow in the nickel diffusion layer 10 of FIG. 1 indicates the decrease in the concentration of nickel in the nickel diffusion layer 10 and the direction of thickness in which the thickness of the nickel diffusion layer 10 can be determined. The nickel diffusion layer is bounded distally opposite the steel component 1 by the surface 12. This surface 12 can itself be coated.

FIG. 2 shows a tensile-elongation diagram resulting from a product according to the invention or a device according to the invention. In the diagram, the nominal stress-indicated in MPa in FIG. 2—is plotted against the elongation (%). The HE value can be determined from this tensile strain diagram or the absorbed (specific) deformation energy can be determined.

The HE value is calculated according to the formula:

$$HE = 1 - \frac{{W}_{B h} ( Deformation energy including H - load )}{{W}_{Bu} ( Deformation energy excluding H - load )}$$

The WBh value is the absorbed (specific) deformation energy of the component, whereby the component has been treated with hydrogen. The WBu value, on the other hand, is the absorbed deformation energy when the component has not been treated with hydrogen. As can be seen schematically in FIG. 2, the absorbed deformation energy of the component treated with hydrogen is only slightly less than the absorbed energy of the component that has not been treated with hydrogen. In other words, no or at most only slight embrittlement has occurred due to the hydrogen.

FIG. 3 shows a further tensile strain diagram of a test in which the components used for the test did not comply with the invention. As can be seen from FIG. 3, the plastic energy absorbed by the component treated with hydrogen is significantly lower than that of the component which was not treated with hydrogen. In the diagrams shown in FIGS. 2 and 3, the fracture of the component with hydrogen treatment or the failure is characterized by an asterisk. The fracture of the component that was not treated with hydrogen is characterized by a cross. The same scales have been used in FIGS. 2 and 3 to enable a comparison.

1. A component comprising:
a steel component,
wherein the component is at least partially coated with a nickel diffusion layer, the layer thickness of the nickel diffusion layer being 1-500 μm,
wherein the nickel diffusion layer has a nickel content, based on the total weight of the nickel diffusion layer, of 2% by weight above the nickel content of the steel up to a maximum concentration,
wherein the nickel content in the nickel diffusion layer increases continuously in the direction of a surface of the nickel diffusion layer from 2% by weight above the nickel content of the steel to the maximum concentration, and
wherein the maximum concentration is 20-100% by weight.

2. The component of claim 1, wherein the component is a fastener,
wherein the component has and/or forms a threaded area and/or shank area,
wherein the component is at least partially coated with the nickel diffusion layer in the threaded area and/or shank area.

3. The component of claim 1, wherein the maximum concentration is 70-99.5% by weight.

4. The component of claim 1, wherein the nickel content in the nickel diffusion layer increases perpendicularly in the direction of the surface of the nickel diffusion layer.

5. The component of claim 1, wherein the layer thickness of the nickel diffusion layer is 5-300 μm.

6. The component of claim 1 wherein a further layer is applied to the nickel diffusion layer, selected from nickel layer comprising ≥90% by weight nickel, based on the total weight of the nickel layer, corrosion protection layer, wear protection layer and sliding layer.

7. The component of claim 1, wherein the steel is a low-alloy steel, a micro-alloy steel or an unalloyed steel.

8. The component of claim 1, wherein the component is selected from the group consisting of high-strength and ultra-high-strength components, welded components, additive-manufactured components, formed components, and/or case-hardened components.

9. The component of claim 1, wherein the component is a high-strength or ultra-high-strength component selected from the group consisting of screws, springs, leaf springs, disc springs and chain drives.

10. A method of manufacturing a component, comprising the steps of:
providing a component with a steel component,
applying a nickel layer comprising ≥30% by weight of nickel, based on the total weight of the nickel layer, to the steel component, and
heating the component and the nickel layer to 750 to 950° C. for at least 10 minutes, preferably at least 20 minutes, thereby producing a nickel diffusion layer on the steel component.

11. The method of claim 10, wherein the nickel layer is applied by electrodeposition, physical vapour deposition (PVD deposition), laser melting, laser metal deposition, and/or build-up welding.

12. The method of claim 10, wherein the layer thickness of the nickel layer applied is 1-100 μm.

13. The method of claim 10, wherein the component made of steel is at least partially coated with the nickel diffusion layer.

14. The method of claim 10, wherein the component is configured for reducing hydrogen embrittlement, in particular use in a battery arrangement and/or a fuel cell.

15. A battery arrangement or fuel cell, comprising:
a component having a fastening means with a threaded area,
wherein the component is at least partially coated with a nickel diffusion layer in the threaded area, the layer thickness of the nickel diffusion layer being 1-500 μm,
wherein the nickel diffusion layer has a nickel content, based on the total weight of the nickel diffusion layer, of 2% by weight above the nickel content of the steel up to a maximum concentration,
wherein the nickel content in the nickel diffusion layer increases continuously in the direction of a surface of the nickel diffusion layer from 2% by weight above the nickel content of the steel to the maximum concentration, and
where the maximum concentration is 20-100% by weight.

16. The battery arrangement or fuel cell of claim 15, wherein the maximum concentration is 70-99.5% by weight.

17. The battery arrangement or fuel cell of claim 15, wherein the nickel content in the nickel diffusion layer increases perpendicularly in the direction of the surface of the nickel diffusion layer.

18. The battery arrangement or fuel cell of claim 15, wherein the layer thickness of the nickel diffusion layer is 5-300 μm.

19. The battery arrangement or fuel cell of claim 15, wherein a further layer is applied to the nickel diffusion layer, selected from nickel layer comprising ≥90% by weight nickel, based on the total weight of the nickel layer, corrosion protection layer, wear protection layer and sliding layer.

20. The battery arrangement or fuel cell of claim 15, wherein the steel is a low-alloy steel, a micro-alloy steel, or an unalloyed steel.
